(19) United States
(12) Patent Application Publication
(10) Pub. No.: US 2009/0039440 A1
(43) Pub. Date: Feb. 12, 2009

(54) SEMICONDUCTOR DEVICE AND METHOD OF FABRICATING THE SAME

(75) Inventor: Akira HOKAZONO, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/186,187

(22) Filed: Aug. 5, 2008

(30) Foreign Application Priority Data
Aug. 6, 2007 (JP) 2007-204068

(51) Int. Cl. H01L 27/092; H01L 21/8238

(52) U.S. Cl. 257/372; 438/199; 257/E27.062; 257/E21.632

(57) ABSTRACT

A semiconductor device comprising: a semiconductor substrate; an n-type MIS transistor which is formed on the semiconductor substrate and has a first metal gate electrode and a first polycrystalline silicon layer formed on the first metal gate electrode; a p-type MIS transistor which is formed on the semiconductor substrate and has a second metal gate electrode and a second polycrystalline silicon layer, the second metal gate electrode containing at least one metallic element different from that of the first metal gate electrode, and the second polycrystalline silicon layer being formed on the second metal gate electrode and having the same conductivity type as that of the first polycrystalline silicon layer.

### CROSS-REFERENCE TO RELATED APPLICATIONS

This application is based upon and claims the benefit of priority from prior Japanese Patent Application No. 2007-204068, filed Aug. 6, 2007, the entire contents of which are incorporated herein by reference.

1. Field of the Invention

The present invention relates to a semiconductor device and method of fabricating the same. For example, the present invention relates to a CMOS device.

2. Description of the Related Art

Heretofore, in CMOS devices, there has been a problem of a parasitic resistance due to a high resistance value in an interface between silicide and silicon formed in source/drain regions. As a related art, Japanese Patent Application Publication No. 2007-19400 discloses a semiconductor device in which conductivity types of polycrystalline silicon in an nMOS gate electrode and a pMOS gate electrode are made the same.

### SUMMARY

According to one aspect of the present invention, there is provided a semiconductor device comprising: a semiconductor substrate; an n-type MIS transistor which is formed on the semiconductor substrate and has a first metal gate electrode and a first polycrystalline silicon layer formed on the first metal gate electrode; a p-type MIS transistor which is formed on the semiconductor substrate and has a second metal gate electrode and a second polycrystalline silicon layer, the second metal gate electrode containing at least one metallic element different from that of the first metal gate electrode, and the second polycrystalline silicon layer being formed on the second metal gate electrode and having the same conductivity type as that of the first polycrystalline silicon layer; a first silicide film formed in source and drain regions of the n-type MIS transistor; a second silicide film which is formed in source and drain regions of the p-type MIS transistor and contains at least one metallic element different from that of the first silicide film; a first on-gate silicide film formed on the first polycrystalline silicon layer; and a second on-gate silicide film which is formed on the second polycrystalline silicon layer and is formed of the same material as that of the first on-gate silicide film.

According to another aspect of the present invention, there is provided a semiconductor device comprising: a semiconductor substrate; an n-type MIS transistor which is formed on the semiconductor substrate and has a first metal gate electrode; a p-type MIS transistor which is formed on the semiconductor substrate and has a second metal gate electrode containing at least one metallic element different from that of the first metal gate electrode; a first silicide film formed in source and drain regions of the n-type MIS transistor; a second silicide film which is formed in source and drain regions of the p-type MIS transistor and contains at least one metallic element different from that of the first silicide film; a first on-gate silicide film formed on the first metal gate electrode; and a second on-gate silicide film which is formed on the second metal gate electrode and is formed of the same material as that of the first on-gate silicide film.

According to another aspect of the present invention, there is provided A method for manufacturing a semiconductor device comprising: forming an n-type well region and a p-type well region in a surface of a semiconductor substrate, the n-type well region and the p-type well region being isolated from each other by an element isolation insulating film; forming a gate insulating film on the semiconductor substrate; forming a first metal film on the n-type well region; forming a second metal film on the p-type well region, the second metal film containing at least one metallic element different from that of the first metal film; forming a polycrystalline silicon film on the first and second metal films; etching the gate insulating film, the first metal film, the second metal film, and the polycrystalline silicon film in order to form a gate electrode on each of the n-type well region and the p-type well region; forming a first silicide film in source and drain regions corresponding to the gate electrode on the n-type well region; forming a second silicide film in source and drain regions corresponding to the gate electrode on the p-type well region, the second silicide film containing at least one metallic element different from that of the first silicide film; and forming a same silicide film on the polycrystalline silicon film forming the gate electrode on each of the n-type well region and the p-type well region.

### BRIEF DESCRIPTION OF THE DRAWINGS

FIG. 1 is a cross-sectional view showing a semiconductor device according to a first embodiment of the present invention;

FIG. 2 is a top view schematically showing gate electrodes of the semiconductor device according to the first embodiment of the present invention;

FIG. 3 is a graph showing C-V characteristic curves of a MOS capacitor used in the semiconductor device according to the first embodiment of the present invention;

FIG. 4 is a cross-sectional view showing a process of manufacturing the semiconductor device according to the first embodiment of the present invention;

FIG. 5 is a cross-sectional view showing a process of manufacturing the semiconductor device according to the first embodiment of the present invention;

FIG. 6 is a cross-sectional view showing a process of manufacturing the semiconductor device according to the first embodiment of the present invention;

FIG. 7 is a cross-sectional view showing a process of manufacturing the semiconductor device according to the first embodiment of the present invention;

FIG. 8 is a cross-sectional view showing a process of manufacturing the semiconductor device according to the first embodiment of the present invention;

FIG. 9 is a cross-sectional view showing a process of manufacturing the semiconductor device according to the first embodiment of the present invention;

FIG. 10 is a cross-sectional view showing a process of manufacturing the semiconductor device according to the first embodiment of the present invention;

FIG. 11 is a cross-sectional view showing a process of manufacturing the semiconductor device according to the first embodiment of the present invention;

FIG. 12 is a cross-sectional view showing a process of manufacturing the semiconductor device according to the first embodiment of the present invention;

FIG. 13 is a cross-sectional view showing a process of manufacturing the semiconductor device according to the first embodiment of the present invention;

FIG. 14 is a cross-sectional view showing a process of manufacturing the semiconductor device according to the first embodiment of the present invention;

FIG. 15 is a cross-sectional view showing a process of manufacturing the semiconductor device according to the first embodiment of the present invention;

FIG. 16 is a cross-sectional view showing a semiconductor device according to a first modified example of the present invention;

FIG. 17 is a cross-sectional view showing a semiconductor device according to a second modified example of the present invention;

FIG. 18 is a cross-sectional view showing a semiconductor device according to a second embodiment of the present invention;

FIG. 19 is a top view schematically showing gate electrodes of the semiconductor device according to the second embodiment of the present invention;

FIG. 20 is a cross-sectional view showing a process of manufacturing the semiconductor device according to the second embodiment of the present invention;

FIG. 21 is a cross-sectional view showing a process of manufacturing the semiconductor device according to the second embodiment of the present invention;

FIG. 22 is a schematic view showing a semiconductor device according to a conventional art; and

FIG. 23 is a schematic view showing the semiconductor device according to the conventional art.

### DETAILED DESCRIPTION OF THE EXEMPLARY EMBODIMENTS

### Comparative Example

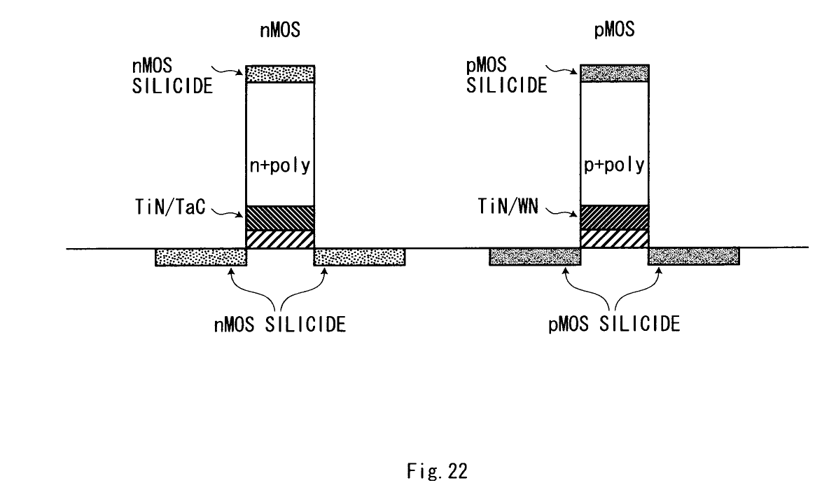

In CMOS devices, there has been a problem of a parasitic resistance due to a high resistance value in an interface between silicide and silicon formed in source/drain regions. Accordingly, as shown in FIG. 22, it is conceivable to use, for an nMOS, a silicide material which exhibits a low Schottky barrier to an n-type region, and to use, for a pMOS, a silicide material which exhibits a low Schottky barrier to a p-type region (dual silicide process). FIG. 22 is a cross-sectional view schematically showing a CMOS device formed by the dual silicide process.

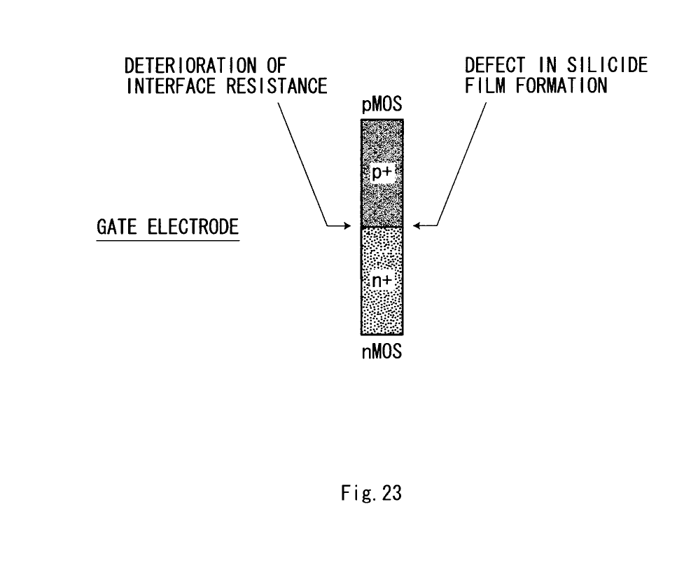

However, in a case where an nMOS gate electrode and a pMOS gate electrode are formed on the same pattern, as shown in FIG. 23, different silicide materials come in contact with each other in the interface between the nMOS region and the pMOS region. FIG. 23 is a top view schematically showing gate electrodes of the CMOS device formed by the dual silicide process. As can be seen in the drawing, in the interface where the materials having the different conductivity types come in contact with each other, a defect in forming a silicide film or disconnection of the gate electrode is anticipated to occur. Further, since dopant is compensated at the junction between the nMOS and the pMOS regions, an interface resistance is expected to deteriorate.

Furthermore, since a gate leak current is likely to increase along with miniaturization of a transistor structure, there arises a problem that a voltage decreases due to the resistance in the interface between silicide and silicon formed on the gate electrode. The voltage decrease means here that a voltage to be applied to the gate electrode is caused to be decreased, which results in deteriorating transistor characteristics.

In response to the above-described problems found by the inventor of the present invention, embodiments of the present invention will be described below by referring to the drawings.

### First Embodiment

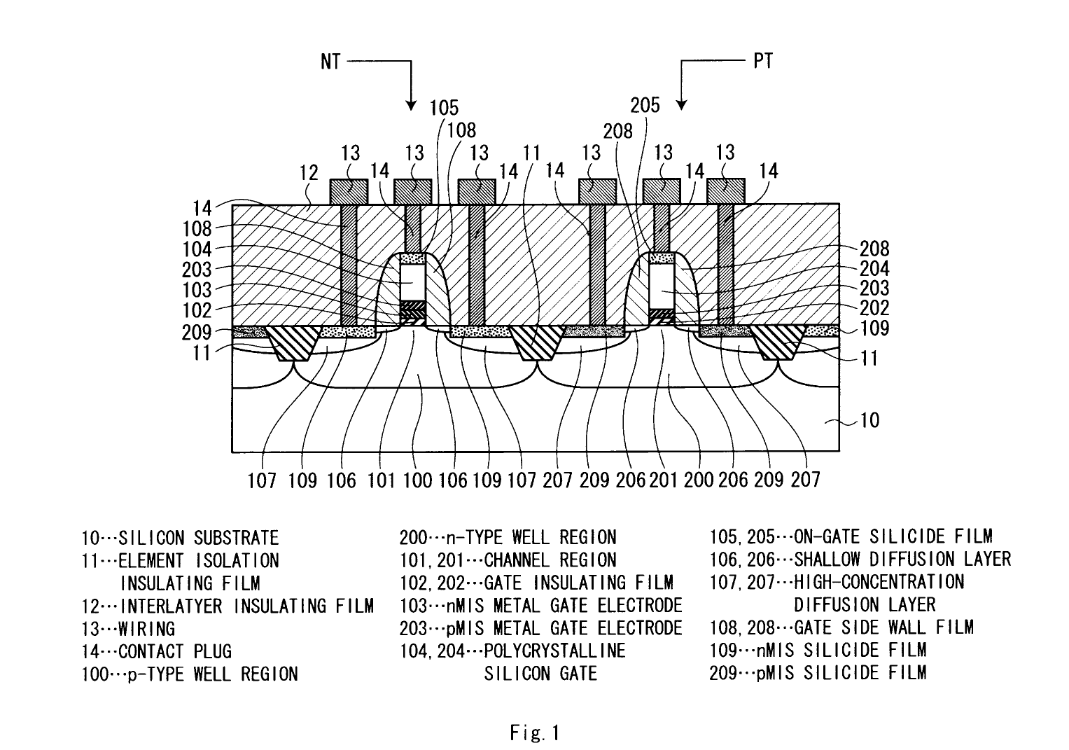

FIG. 1 is a cross-sectional view of a semiconductor device according to a first embodiment of the present invention.

As shown in FIG. 1, a p-type well region 100 and an n-type well region 200 are formed on a p-type semiconductor layer or an n-type semiconductor layer inside a silicon substrate 10. The p-type well region 100 and the n-type well region 200 are separated from each other by an element isolation insulating film 11. An n-type MIS (metal-insulator-silicon) transistor NT and a p-type MIS transistor PT are respectively formed in the p-type well region 100 and the n-type well region 200.

The n-type MIS transistor NT includes: a channel region 101; a gate insulating film 102; a metal gate electrode of an n-type MIS transistor (hereinafter referred to as nMIS metal gate electrode) 103; a metal gate electrode of a p-type MIS transistor (hereinafter referred to as pMIS metal gate electrode) 203; a polycrystalline silicon layer 104; an on-gate silicide film 105; and source/drain regions including shallow diffusion layers 106 and high-concentration diffusion layers 107.

The gate insulating film 102 is formed on the channel region 101 formed between the shallow diffusion layers 106. The nMIS metal gate electrode 103 is formed on the gate insulating film 102. The pMIS metal gate electrode 203 is formed on the nMIS metal gate electrode 103. The polycrystalline silicon layer 104 is formed on the pMIS metal gate electrode 203 with an unillustrated barrier film interposed therebetween. The on-gate silicide film 105 is formed on the polycrystalline silicon layer 104. A gate length L of the n-type MIS transistor NT is, for example, 25 nm.

The gate insulating film 102 is formed of, for example, an HfSiON film. Incidentally, the gate insulating film 102 may also be formed of HfSiO, SiO₂, Si₃N₄, Al₂O₃, Ta₂O₅, TiO₂, La₂O₅, CeO₂, ZrO₂, HfO₂, SrTiO₃, Pr₂O₃, or the like. In addition, a material in which a metal ion is mixed in a silicon oxide, such as Zr silicate and Hf silicate, is also available.

The nMIS metal gate electrode 103 has a film-thickness of approximately 5 nm to 30 nm, and is formed of, for example, TaC having a work function (WF) of around 4.05 eV in order to obtain a threshold voltage at which the nMIS metal gate electrode 103 is operable as the n-type MIS transistor (IEDM Tech. Dig., 287 (2004) by J. K. Schaeffer, et al., discloses characteristics of the n-type MIS transistor using TaC as a metal gate electrode). Incidentally, the nMIS metal gate electrode 103 may be formed of: Ti having a work function of around 4.05 as similar to TaC; Mo in which Ar+ ion is implanted; and TaN, RuTa, Ta, and the like each in which a work function thereof is controlled by a nitrogen (N) concentration.

Gate side wall films 108 are formed on the side surfaces of the stacked gate structure of the n-type MIS transistor NT including the gate insulating film 102, nMIS metal gate electrode 103, pMIS metal gate electrode 203, polycrystalline silicon layer 104, and on-gate silicide film 105. The bottom portions of the gate side wall films 108 come in contact with the upper surfaces of the shallow diffusion layers 106.

Each of the shallow diffusion layers 106 is an n-type extension region and protrudes to the channel region 101 side more than the high-concentration diffusion layers 107. Each of the high-concentration diffusion layers 107 is formed in a portion deeper than the shallow diffusion layers 106 in the p-type well region 100, and is an n-type impurity diffusion region with a higher concentration than those of the shallow diffusion layers 106.

The p-type MIS transistor PT includes: a channel region 201; a gate insulating film 202; the pMIS metal gate electrode 203; a polycrystalline silicon layer 204; an on-gate silicide film 205; and source/drain regions including shallow diffusion layers 206 and high-concentration diffusion layers 207.

The gate insulating film 202 is formed on the channel region 201 formed between the shallow diffusion layers 206. The pMIS metal gate electrode 203 is formed on the gate insulating film 202. The polycrystalline silicon layer 204 is formed on the pMIS metal gate electrode 203 with an unillustrated barrier film interposed therebetween. The on-gate silicide film 205 is formed on the polycrystalline silicon layer 204. A gate length L of the p-type MIS transistor PT is, for example, 25 nm.

The gate insulating film 202 is formed of, for example, HfSiON as similar to the gate insulating film 102. The pMIS metal gate electrode 203 has a film-thickness of approximately 5 nm to 30 nm, and is formed of, for example, WN having a work function of around 5.17 eV in order to obtain a threshold voltage at which the pMIS metal gate electrode 203 is operable as the p-type MIS transistor. Similarly, TiNi (WF is 5.3), NiGe (WF is 5.2), Pt (WF is 5.2), Ru, or W, each having a work function of around 5.17, may also be used as the metal gate electrode 203 (VLSI Tech. Dig., p 192 (2004) by V. Narayanan, et al., discloses characteristics of the p-type MIS transistor using W as a metal gate electrode).

Although it is not explicitly shown in FIG. 1, for example, TiN may be formed on the metal gate electrodes 203 included in the n-type MIS transistor NT and the p-type MIS transistor PT as a barrier film for preventing a reaction between each of the metal gate electrodes 203 and each of the polycrystalline silicon layers formed thereabove. Note that the metal gate electrode 203 included in the n-type MIS transistor NT is a metal film which is formed by the same processes as those of the metal gate electrode 203 included in the p-type MIS transistor PT, and is caused to be left by using a manufacturing method to be described later.

In other words, the metal gate electrode 203 included in the n-type MIS transistor NT is not necessarily needed and may be removed. The reason is that a threshold voltage of the n-type MIS transistor NT is determined only by a metal film formed directly on the gate insulating film 102, that is, the metal gate electrode 103 in this embodiment.

Gate side wall films 208 are formed on the side surfaces of the stacked gate structure of the p-type MIS transistor PT including the gate insulating film 202, pMIS metal gate electrode 203, polycrystalline silicon layer 204, and on-gate silicide film 205. The bottom portions of the gate side wall films 208 come in contact with the upper surfaces of the shallow diffusion layers 206.

Each of the shallow diffusion layers 206 is a p-type extension region and protrudes to the channel region 201 side more than the high-concentration diffusion layers 207. Each of the high-concentration diffusion layers 207 is formed in a portion deeper than the shallow diffusion layers 206 in the n-type well region 200, and is a p-type impurity diffusion region with a higher concentration than those of the shallow diffusion layers 206. The source/drain regions of the p-type MIS transistor PT including the shallow diffusion layers 206 and the high-concentration diffusion layers 207 are separated from the source/drain regions of the adjacent n-type MIS transistor through the element isolation insulating film 11.

On the surfaces of the source/drain regions of the n-type MIS transistor NT and the source/drain regions of the p-type MIS transistor PT, silicide films whose materials are different from each other are formed (dual silicide structure). Specifically, a material which exhibits a low Schottky barrier to an n-type region is used for the source/drain regions of the n-type MIS transistor NT, to thereby form nMIS silicide films 109. Similarly, a material which exhibits a low Schottky barrier to a p-type region is used for the source/drain regions of the p-type MIS transistor PT, to thereby form pMIS silicide films 209.

As the nMIS silicide films 109 to be formed in the n-type source/drain regions, for example, YSi₂₋ₓ, YSi, ErSi_{1.7}, YbSi₂, or the like can be used. Meanwhile, as the pMIS silicide films 209 to be formed in the p-type source/drain regions, for example, PtSi, Pd₂Si, NiSi, or the like can be used.

The polycrystalline silicon layers 104 and 204 each have a film-thickness of 50 nm to 100 nm and both of which are n+ doping layers with the same concentration. The on-gate silicide films 105 and 205 are formed of the same material, and are formed of a material which exhibits a low Schottky barrier to an n-type region depending on dopant in the respective polycrystalline silicon layers 104 and 204. As the on-gate silicide films 105 and 205, for example, YSi₂₋ₓ, YSi, ErSi_{1.7}, YbSi₂, or the like can be used.

For the sake of simplicity of processes and the like, it is desirable that the on-gate silicide films 105 and 205 be formed of the same material as that of the nMIS silicide film 109 formed in the source/drain regions of the n-type MIS transistor NT.

An interlayer insulating film 12 is formed on the entire surface of the silicon substrate 10, element isolation insulating film 11, n-type MIS transistor NT, p-type MIS transistor PT, gate side wall film 108 and gate side wall film 208. Wirings 13 each having a desired pattern are formed on the interlayer insulating film 12. In the interlayer insulating film 12, contact plugs 14 each connecting each of the on-gate silicide film 105, on-gate silicide film 205, nMIS silicide film 109, and pMIS silicide film 209 with each of the wirings 13 are formed. An unillustrated barrier film which prevents a metallic element forming the contact plugs 14 from spreading is formed between the interlayer insulating film 12 and each of the contact plugs 14.

The interlayer insulating film 12 is formed of, for example, TEOS (tetraethoxysilane), BPSG (boron phosphorous silicate glass), or the like. The wirings 13 are each formed of, for example, Al. The contact plugs 14 are each formed of, for example, W. The barrier film is formed of, for example, Ti, TiN, or the like.

In the semiconductor device having the above-described structure, the source/drain regions have a dual silicide structure, and the work functions of the gate electrodes are determined depending on the metal gate electrodes respectively included in the n-type MIS transistor and p-type MIS transistor. Further, the polycrystalline silicon layers on the metal gate electrodes are the same n+ doping layer, and the on-gate silicide films are each formed of a material which exhibits a low Schottky barrier to an n-type region.

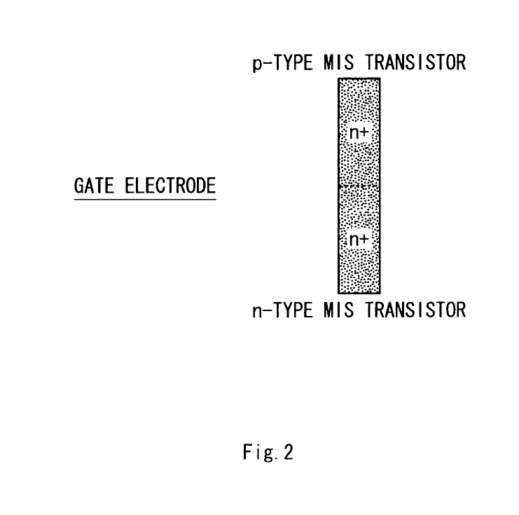

FIG. 2 is a top view schematically showing the gate electrodes of the semiconductor device according to the present embodiment. As shown in FIG. 2, an interface between the n-type region and the p-type region is not formed in forming the gate electrodes of the semiconductor device having the dual silicide structure. In other words, there is no interface between the polycrystalline silicon layers having different conductivity types, so that deterioration of an interface resistance due to dopant compensation can be prevented. In addition, there is no interface between the on-gate silicide films formed of different materials, so that a defect in forming a silicide film can be prevented and disconnection of the gate electrode can be prevented. Moreover, a combination of materials of the on-gate silicide film and dopant of the polycrystalline silicon layer can be selected so that the Schottky barrier would be lowered in the n-type region. Accordingly, the deterioration of resistance in the interface between silicide and silicon formed on each gate electrode can be prevented.

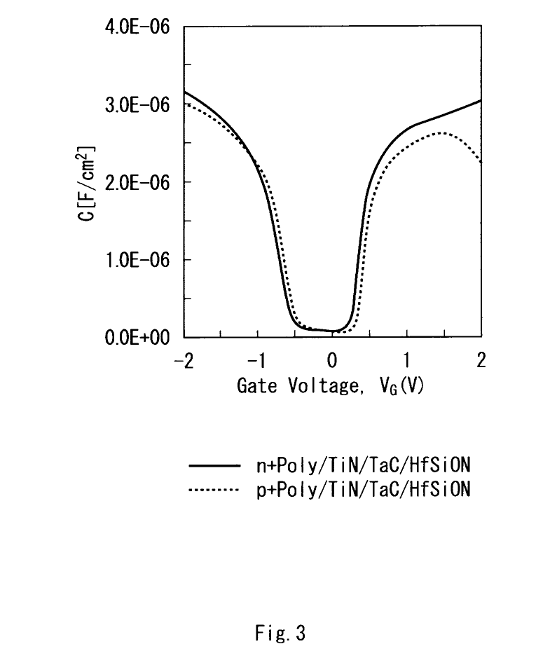

It is confirmed by the applicant that the threshold voltage of the MIS transistor is determined not by the conductivity type of the polycrystalline silicon layer but by the metal gate electrode formed directly on the gate insulating film. Description will be given as to this point by referring to FIG. 3. FIG. 3 is a graph showing capacity C (F/cm²)-gate voltage V_{G} (V) characteristics in a case where HfSiON as a gate insulating film, TaC as a metal gate electrode, and TiC as a barrier film are used and a polycrystalline silicon layer is formed as an n+ doping layer (solid line), and where HfSiON as a gate insulating film, TaC as a metal gate electrode, and TiC as a barrier film are used and a polycrystalline silicon layer is formed as a p+ doping layer (dotted line).

As is clear from FIG. 3, these two curves show substantially the same behaviors and have the same flat-band voltage. In essence, the threshold voltage of the MIS transistor can be controlled not by the conductivity type of the polycrystalline silicon layer but by the metal gate electrode formed directly on the gate insulating film.

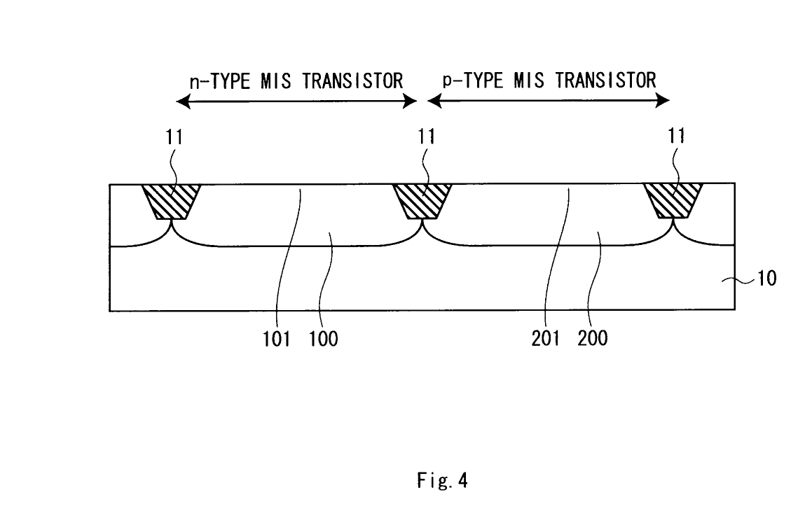

A method for manufacturing the semiconductor device shown in FIG. 1 will now be described below by referring to FIGS. 4 to 15.

The element isolation insulating film 11 with a depth of 200 nm to 350 nm is formed on the silicon substrate 10 having a p-type semiconductor layer or an n-type semiconductor layer by a buried element isolation method. Subsequently, an unillustrated sacrificial oxide film with a thickness of 20 nm or less is formed in an active element portion in order to avoid damages on the surface of the silicon substrate 10 caused by ion implantation.

After that, ion implantation is carried out to form the p-type well region 100, n-type well region 200, and channel regions 101 and 201. The ion implantation is carried out in the following manner. Specifically, B ion implantation is performed under the conditions of 260 keV and 2.0×10¹³ cm-² to form the p-type well region 100; P ion implantation is performed under the conditions of 500 keV and 3.0×10¹³ cm⁻² to form the n-type well region 200; As ion implantation is performed under the conditions of 80 keV and 1.0×10¹³ cm⁻² to form the channel region 101; and B ion implantation is performed under the conditions of 10 keV and 1.5×10¹³ cm⁻² to form the channel region 201. Then, activation RTA (rapid thermal oxidation) is carried out at 1080° C. (FIG. 4).

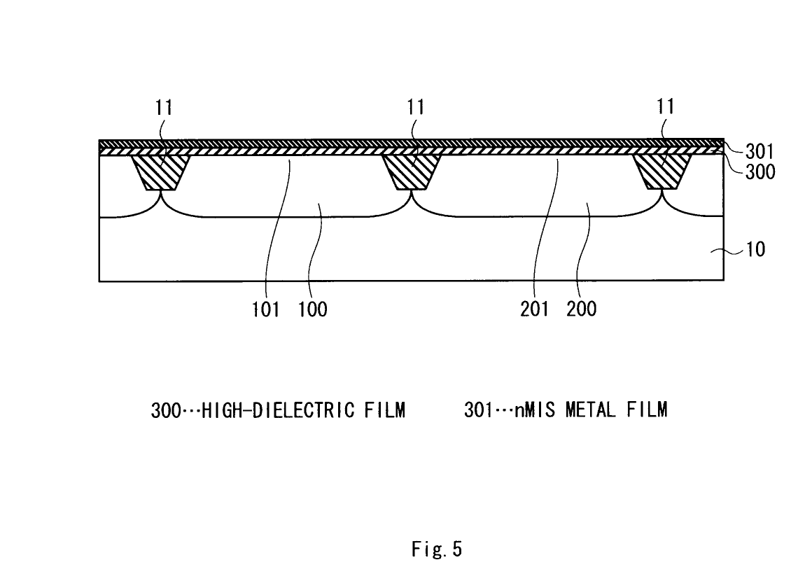

Next, an HfSiO film with a thickness of 0.5 nm to 2 nm is formed on the silicon substrate 10 by the MOCVD method (metal organic chemical vapor deposition) method. This HfSiO film is subjected to plasma nitridation to form a high-dielectric film 300 formed of HfSiON. Subsequently, an nMIS metal film (first metal film) 301 formed of TaC is deposited on the high-dielectric film 300 with a film-thickness of 5 nm to 30 nm by sputtering (FIG. 5).

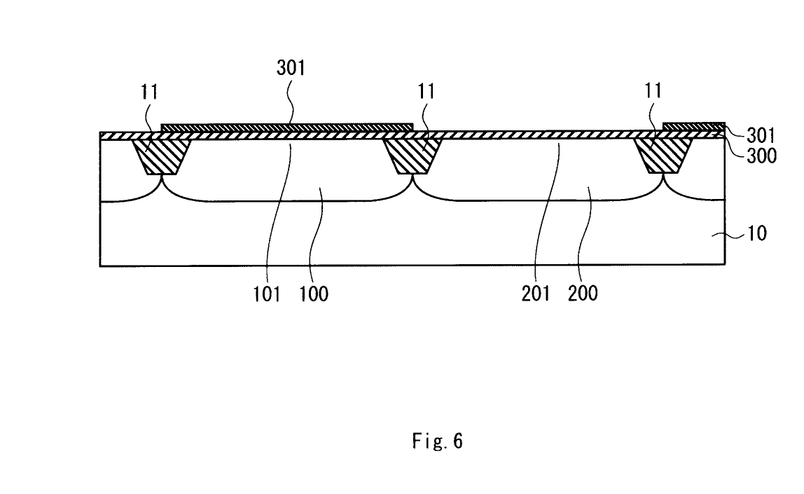

After that, the n-type MIS transistor region is covered with a photoresist and the nMIS metal film 301 deposited on the p-type MIS transistor region is removed by RIE, or wet etching using a mixed solution of sulfuric acid and a hydrogen peroxide solution. Consequently, in the n-type MIS transistor region, the nMIS metal film 301 is formed on the high-dielectric film 300. In the p-type MIS transistor region, the surface of the high-dielectric film 300 is exposed. An end portion of the nMIS metal film 301 is on the element isolation insulating film 11 (FIG. 6).

Subsequently, a pMIS metal film (second metal film) 302 formed of WN is uniformly deposited on the high-dielectric film 300 and the nMIS metal film 301 with a film-thickness of 5 nm to 30 nm by sputtering. In the present embodiment, a process in which the pMIS metal gate film 302 deposited on the nMIS metal film 301 is not removed is employed. A step is generated between the pMIS metal film 302 formed on the high-dielectric film 300 and the pMIS metal film 302 formed on the nMIS metal film 301. However, this step is on the element isolation insulating film 11, and thus it does not cause a problem.

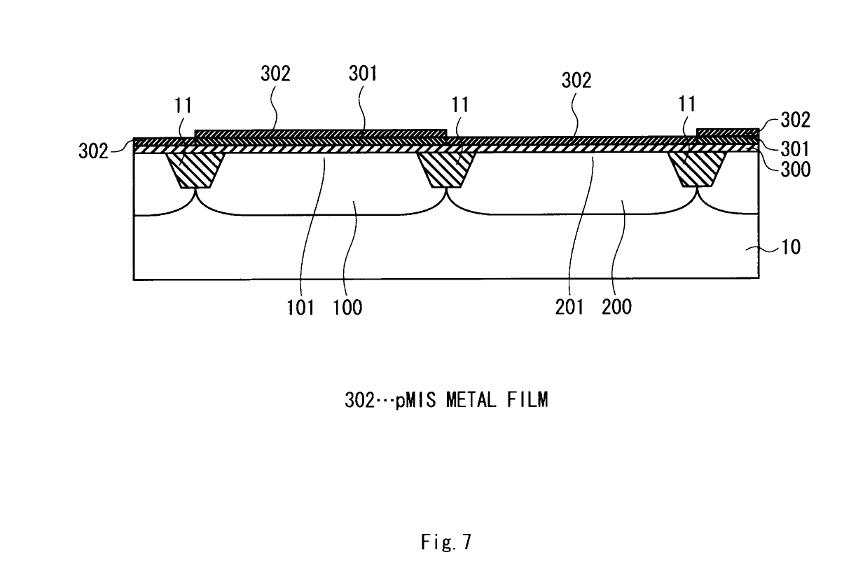

In addition, as described above, the threshold voltage of the MIS transistor is determined by the metal gate electrode formed directly on the gate insulating film. Accordingly, even if the pMIS metal film 302 is left on the nMIS metal film 301, it does not cause a problem on characteristics. Employing the process without removing the pMIS metal film 302 simplifies the manufacturing processes. Note, however, that the pMIS metal film 302 on the nMIS metal film 301 can be naturally removed by a CMP (chemical vapor deposition) method or the like (FIG. 7).

Next, an unillustrated barrier film formed of TiN is deposited on the pMIS metal film 302 by sputtering. Subsequently, a polycrystalline silicon film is deposited on the pMIS metal film 302 with the barrier film interposed therebetween with a film-thickness of 50 nm to 100 nm by a LPCVD (low pressure chemical vapor deposition) method. After that, an n+ doping layer is formed on the entire surface of this polycrystalline silicon film by ion implantation. Here, the n+ doping layer can be formed by P ion implantation under the conditions of 5 keV and 5.0×10¹⁵, As ion implantation under the conditions of 20 keV and 3 to 5×10¹⁵, or the like. Then, a silicon nitride film is deposited on the polycrystalline silicon film with a film-thickness of 60 nm to 80 nm, and the gate electrode is processed by using the photoresist on which a gate wiring pattern is transferred as a mask.

With the gate electrode process, the gate insulating film 102, nMIS metal gate electrode 103, pMIS metal gate electrode 203, and polycrystalline silicon layer 104, which form the stacked gate structure of the n-type MIS transistor NT, are obtained. Similarly, the gate insulating film 202, pMIS metal gate electrode 203, and polycrystalline silicon layer 204, which form the stacked gate structure of the p-type MIS transistor PT, are obtained. Hereinafter, the silicon nitride film left on the polycrystalline silicon layer 104 is referred to as a hard mask 110 and the silicon nitride film left on the polycrystalline silicon layer 204 is referred to as a hard mask 210.

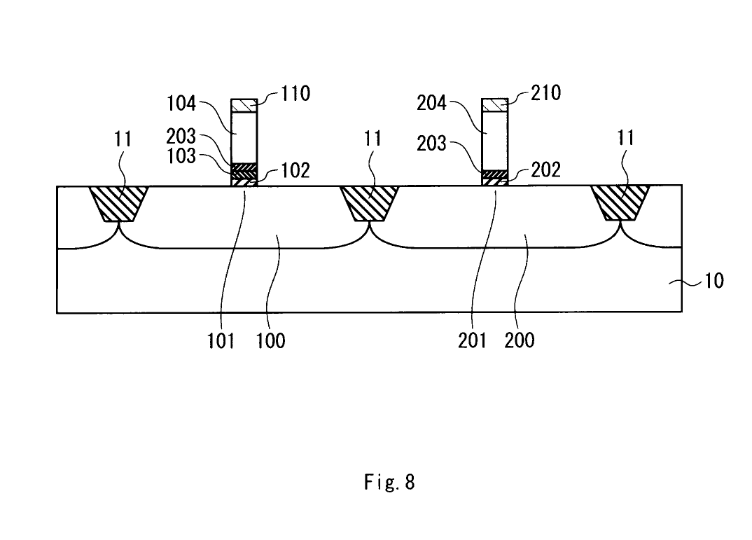

The reason why the polycrystalline silicon layer is formed on the metal gate electrode here is that the film thickness of the metal material to be etched is thinly formed because it is difficult to perform RIE on the gate electrode formed of the metal material, and that contamination of the manufacturing device is prevented by capping the metal material (FIG. 8).

Next, an unillustrated offset spacer formed of a silicon nitride film is formed on the sidewall of the stacked gate structure with a film-thickness of 3 nm to 15 nm. This is a spacer film for maintaining the controllability of the ion implantation even in a case where a gate length L is short (for example, 25 nm or less). Subsequently, the shallow diffusion layers 106 and 206 are formed by using the hard mask 110, hard mask 210, and offset spacer on the stacked gate structure as masks.

The shallow diffusion layer 106 is an n-type diffusion layer and is formed by As ion implantation under the conditions of 1 to 5 keV and 5.0×10¹⁴ cm⁻² to 1.5×10¹⁵ cm⁻². The shallow diffusion layer 206 is a p-type diffusion layer and is formed by BF₂ ion implantation under the conditions of 1 to 3 keV and 5.0×10¹⁴ cm⁻² to 1.5×10¹⁵ cm⁻². Any of the shallow diffusion layers 106 and 206 can be formed first. After that, activation RTA is carried out at 1000° C.

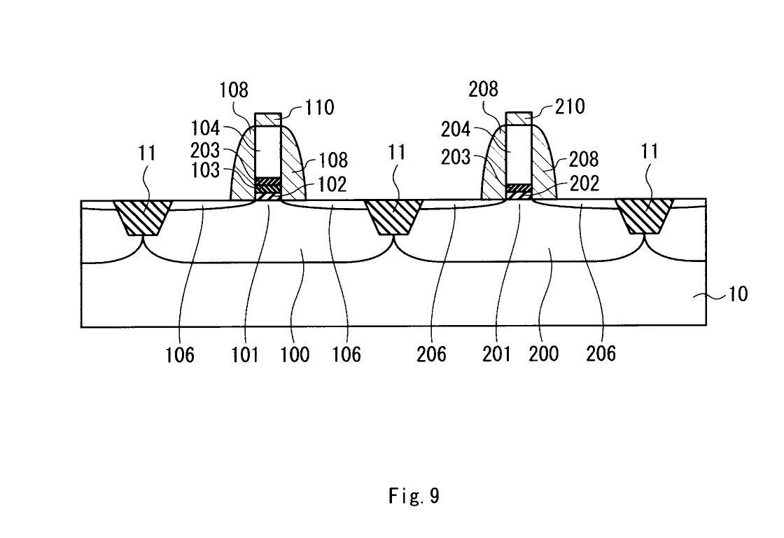

Next, the gate side wall films 108 and 208, formed of TEOS or a laminated film of TEOS and SiN, are formed on the sidewall of the stacked gate structure with the offset spacer interposed therebetween. The gate side wall films 108 and 208 each have a width of 20 nm to 70 nm on the silicon substrate 10. The upper ends of the gate side wall films 108 and 208 respectively reach the interfaces between the polycrystalline silicon layer 104 and hard mask 110 and between the polycrystalline silicon layer 204 and hard mask 210 (FIG. 9).

Then, the high-concentration diffusion layers 107 and 207 are formed by ion implantation by using the hard masks 110 and 210, and gate side wall films 108 and 208 on the stacked gate structure as masks. The high-concentration diffusion layer 107 is an n-type diffusion layer with a higher concentration than the shallow diffusion layer 106, and is formed by As ion implantation under the conditions of 20 to 30 keV and 3.0×10¹⁵ to 4.0×10¹⁵ cm⁻². The high-concentration diffusion layer 207 is a p-type diffusion layer with a higher concentration than the shallow diffusion layer 206 and is formed by B ion implantation under the conditions of 1.5 to 3.0 keV and 2.0×10¹⁵ to 4.0×10¹⁵ cm⁻².

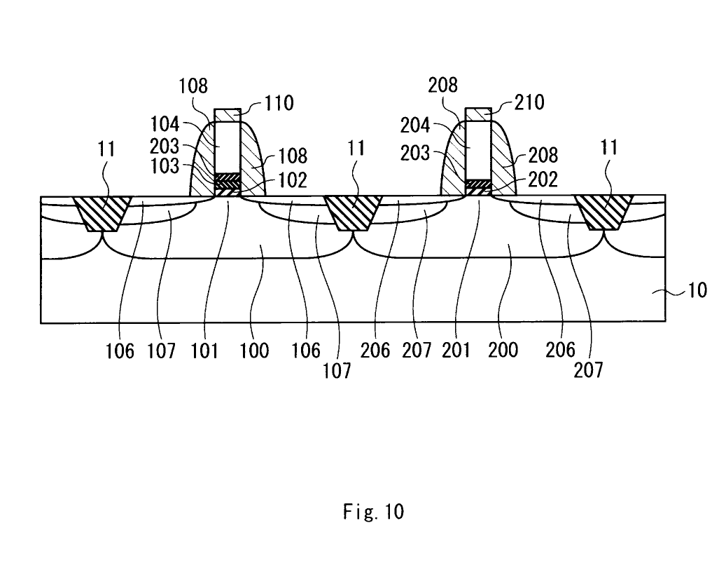

Any of the high-concentration diffusion layers 107 and 207 can be formed first. Then, activation RTA is carried out at 1050° C. (FIG. 10).

Incidentally, before forming the high-concentration diffusion layers 107 and 207, a process of epitaxially growing Si or SiGe selectively on the silicon substrate 10 may also be applied. Thereby, the ion implantation profiles of the high-concentration diffusion layers 107 and 207 can be preferably controlled.

Next, only the p-type MIS transistor region is coated with a silicon oxide film (or silicon nitride film) 303 for forming the source/drain regions by the dual silicide process. Then, hydrofluoric acid treatment is carried out to remove a natural oxide film, so that the nMIS silicide film 109 is formed in the source/drain regions of the n-type MIS transistor NT.

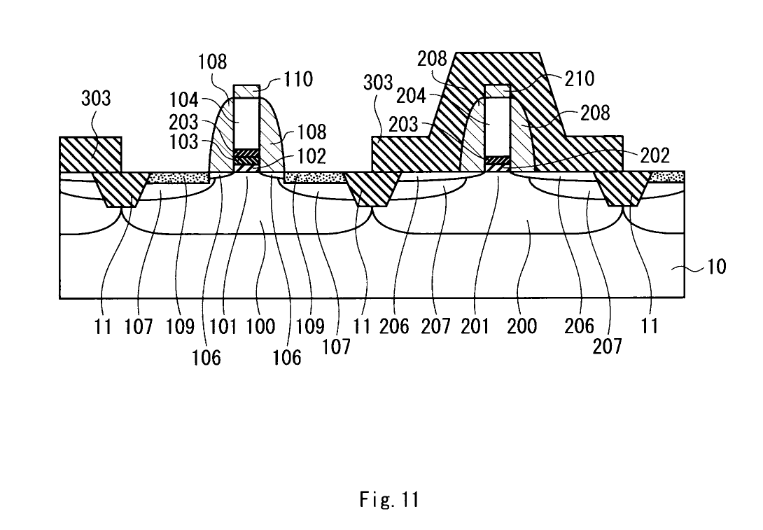

If the nMIS silicide film 109 formed of Er silicide is formed, Er is deposited on the entire surface by sputtering, and thereafter, RTA for silicidation is carried out under the condition of 400° C. to 500° C. Thereby, the nMIS silicide film 109 with a film-thickness of 10 nm to 35 nm is formed in the source/drain regions of the n-type MIS transistor NT. Unreacted Er is removed by etching using a mixed solution of sulfuric acid and a hydrogen peroxide solution. With the processes described above, the Er silicide process is completed (FIG. 11).

Next, the silicon oxide film (or silicon nitride film) 303 coating the p-type MIS transistor region is removed by fluorinated acid or phosphoric acid heated to 120° C. to 130° C. (hot phosphoric acid). Subsequently, in the same manner as above, only the n-type MIS transistor region is coated with a silicon oxide film (or silicon nitride film). Then, if needed, hydrofluoric acid treatment is carried out to remove a natural oxide film, so that the pMIS silicide film 209 is formed in the source/drain regions of the p-type MIS transistor PT.

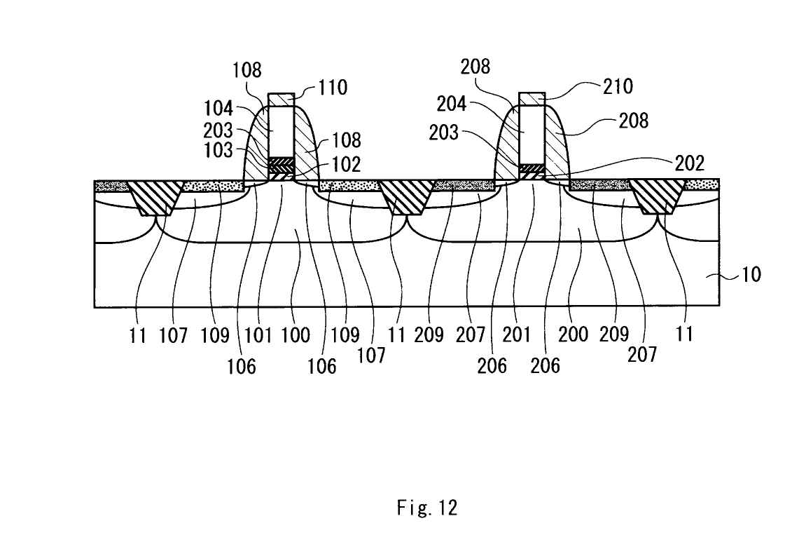

If the pMIS silicide film 209 formed of Pt silicide or Pd silicide is formed, Pt or Pd is deposited on the entire surface by sputtering, and thereafter, RTA for silicidation is carried out under the condition of 400° C. to 500° C. Thereby, the pMIS silicide film 209 with a film-thickness of 10 nm to 35 nm is formed in the source/drain regions of the p-type MIS transistor PT. In the case of Pt silicide or Pd silicide, aqua regia can be used to selectively separate silicide from the unreacted metal. With the processes described above, the Pt or Pd silicide process is completed (FIG. 12).

In the dual silicide process carried out on the above-descried source/drain regions, the nMIS silicide film 109 is formed first. Note that, however, the present invention is not limited to this, and the pMIS silicide film 209 may be formed first.

After that, the silicon oxide film (or silicon nitride film) covering the n-type MIS transistor region is removed by fluorinated acid or hot phosphoric acid. Then, RIE for forming a contact hole to be described later is carried out to bore the nMIS silicide film 109 and pMIS silicide film 209 formed on the silicon substrate 10. Thus, in order to prevent junction leak current from increasing, an unillustrated silicon nitride film, whose selection ratio of RIE is high for the material of the interlayer insulating film, is formed with a film-thickness of 20 nm to 50 nm on the nMIS silicide film 109 and the pMIS silicide film 209.

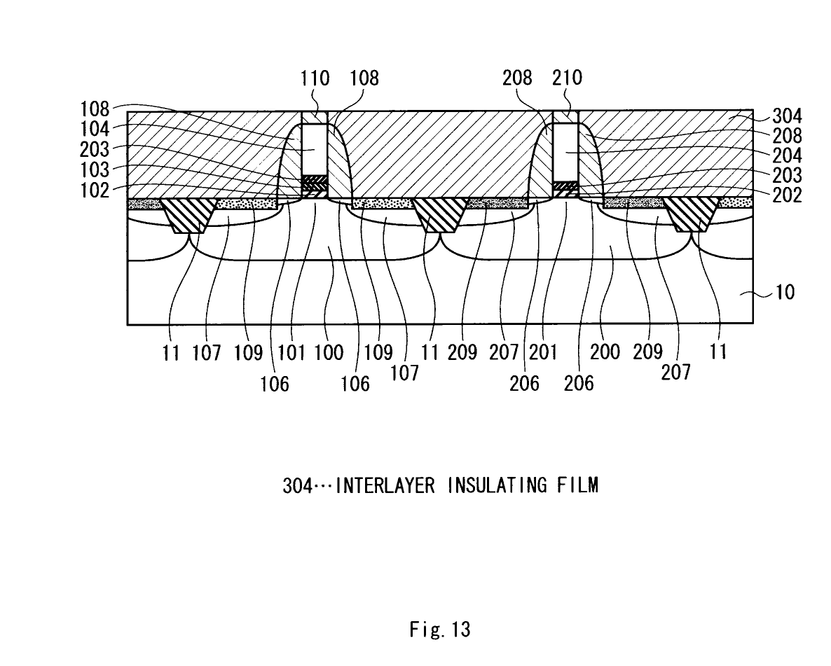

Then, an interlayer insulating film 304 formed of TEOS or BPSG is deposited on the entire surface, and the thus deposited film is polished by a CMP process for planarization. Here, the hard masks 110 and 210 are used as stopper films for CMP (FIG. 13).

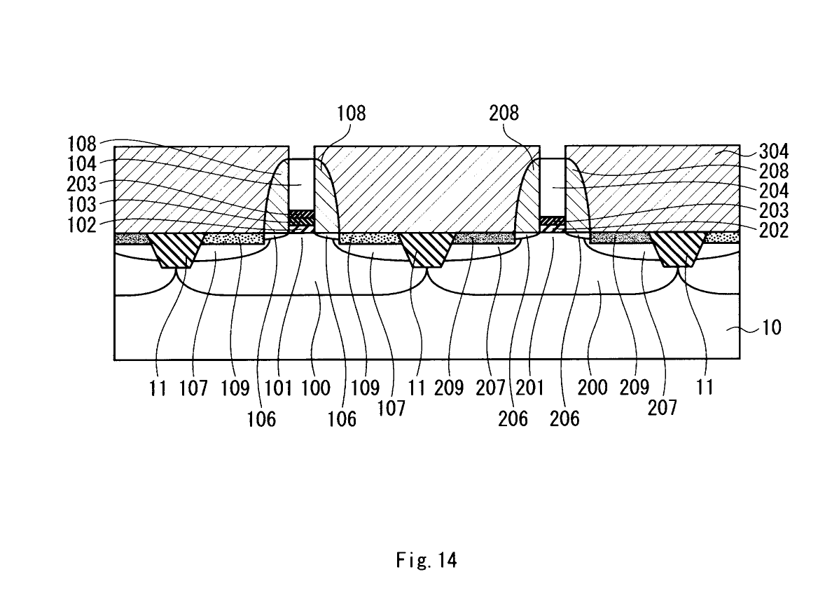

Next, the hard masks 110 and 210 being exposed from the surface of the interlayer insulating film 304 are removed by hot phosphoric acid to expose the polycrystalline silicon layers 104 and 204 (FIG. 14).

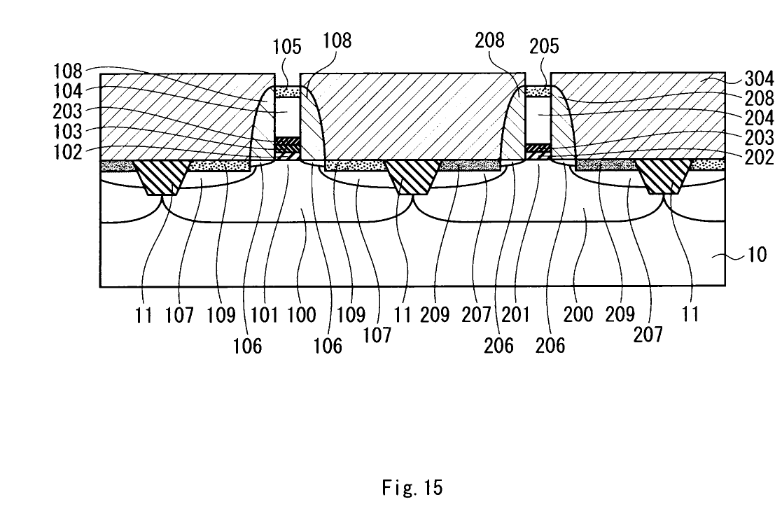

Subsequently, the on-gate silicide films 105 and 205 are formed by using a silicide material corresponding to the dopant in the polycrystalline silicon layers 104 and 204 (in the present embodiment, an n+ doping layer is employed, and thus the dopant is P, As, or the like). Here, the n+ doping layer is formed in the polycrystalline silicon layers 104 and 204. Accordingly, a material which exhibits a low Schottky barrier to an n-type region, such as Er silicide, can be used to form the on-gate silicide films 105 and 205 (FIG. 15).

Next, the interlayer insulating film 12 is formed by depositing a material same as that of the interlayer insulating film 304 (TEOS or BPSG) on the on-gate silicide film 105, on-gate silicide film 205, and interlayer insulating film 304. Subsequently, an exposure process for forming a contact hole is carried out to perform RIE on the interlayer insulating film 12 by using the photoresist on which the contact hole pattern is transferred as a mask. This etching continues until the silicon nitride film on the nMIS silicide film 109 and pMIS silicide film 209 described above is exposed. Thereafter, a silicide surface with less damage is obtained by removing only this silicon nitride film by wet etching or the like.

Subsequently, Ti or TiN is deposited on the inner wall of the contact hole as a barrier film. Then, a blanket W is deposited inside the contact hole, and the thus deposited film is polished by a CMP process until the surface of the interlayer insulating film 12 is exposed. Thereby, the contact plugs 14 each reaching the nMIS silicide film 109 and pMIS silicide film 209 are formed.

Next, a metal film formed of Al is deposited on the interlayer insulating film 12, and then an exposure process for a wiring formation is carried out. Subsequently, RIE is carried out by using the photoresist on which the wiring pattern is transferred as a mask, so that the wirings 13 electrically connected to the contact plugs 14 are formed on the interlayer insulating film 12. With the processes described above, the semiconductor device shown in FIG. 1 is obtained.

### First Modified Example

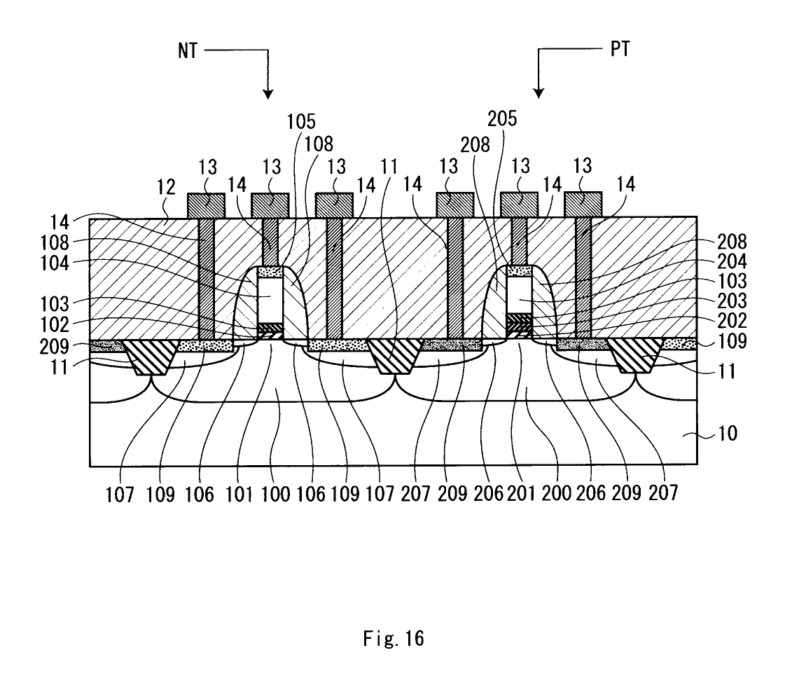

FIG. 16 is a cross-sectional view showing a semiconductor device according to a first modified example. The first modified example is different from the first embodiment in the configuration of the stacked gate structure of an n-type MIS transistor NT and a p-type MIS transistor PT.

Specifically, the n-type MIS transistor NT has a stacked gate structure including a gate insulating film 102, an nMIS metal gate electrode 103 (and unillustrated barrier film), a polycrystalline silicon layer 104, and an on-gate silicide film 105. The p-type MIS transistor PT has a stacked gate structure including a gate insulating film 202, a pMIS metal gate electrode 203, the nMIS metal gate electrode 103 (and unillustrated barrier film), a polycrystalline silicon layer 204, and an on-gate silicide film 205. This difference is caused by the following differences in manufacturing processes.

In the first embodiment, the nMIS metal film 301 is formed on the high-dielectric film 300 prior to forming the pMIS metal film 302. In contrast, in the first modified example, a pMIS metal film 302 is formed on a high-dielectric film 300 prior to forming an nMIS metal film 301. Subsequently, the p-type MIS transistor forming region is covered with a photoresist, and the pMIS metal film 302 deposited on the n-type MIS transistor forming region is removed. Thereafter, the nMIS metal film 301 is deposited on the high-dielectric film 300 and the pMIS metal film 302 by sputtering. Then, a barrier film formed of TiN or the like is deposited on the nMIS metal film 301. Thereafter, the semiconductor device shown in FIG. 16 is obtained by similar processes to those of the first embodiment.

As described above, the threshold voltage of the MIS transistor is determined by the metal gate electrode formed directly on the gate insulating film. Accordingly, differences in the transistor characteristics, such as threshold voltages, between the cases where the nMIS metal gate electrode 103 is present on the pMIS metal gate electrode 203 as in the first modified example and where the pMIS metal gate electrode 203 is present on the nMIS metal gate electrode 103 as in the first embodiment, can be almost negligible. Thus, the effects obtained by the semiconductor device according to the first embodiment can be similarly obtained by the semiconductor device according to the first modified example.

Similar to the first embodiment, the nMIS metal film 301 on the pMIS metal film 302 can be naturally removed.

### Second Modified Example

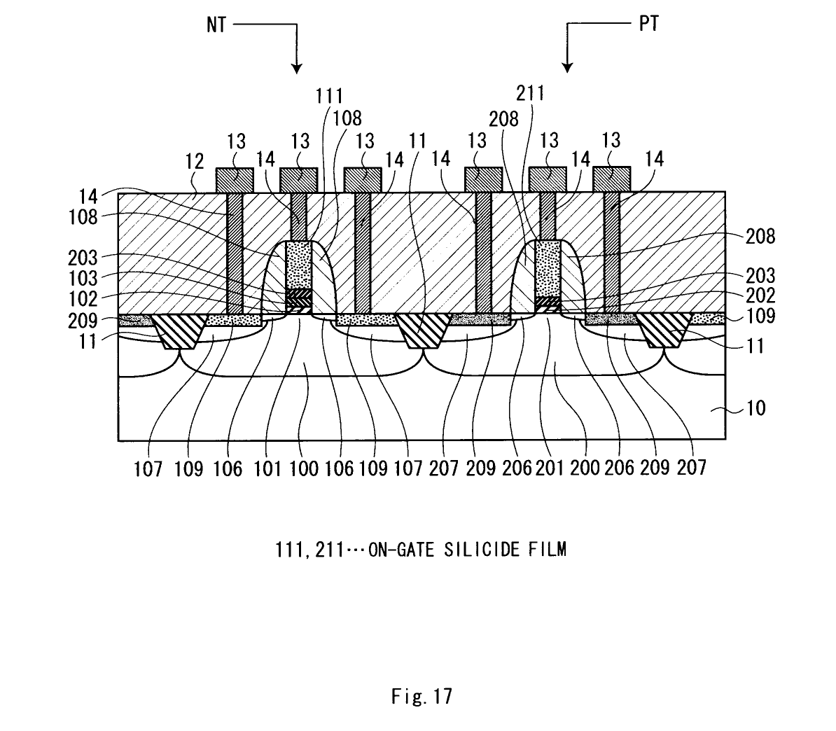

FIG. 17 is a cross-sectional view showing a semiconductor device according to a second modified example. The second modified example is different from the first embodiment in the configuration of the stacked gate structure of an n-type MIS transistor NT and a p-type MIS transistor PT.

Specifically, the n-type MIS transistor NT has a stacked gate structure including a gate insulating film 102, nMIS metal gate electrode 103, pMIS metal gate electrode 203 (and unillustrated barrier film), and on-gate silicide film 111. The p-type MIS transistor PT has a stacked gate structure including a gate insulating film 202, pMIS metal gate electrode 203 (and unillustrated barrier film), and on-gate silicide film 211. In essence, differing from the first embodiment, all the polycrystalline silicon layers on the metal gate electrodes are subjected to silicidation.

To obtain the semiconductor device shown in FIG. 17, similar to the first embodiment, polycrystalline silicon layers 104 and 204 are formed on the pMIS metal gate electrode 203, and thereafter, a sufficient amount of metal films such that all of the polycrystalline silicon layers 104 and 204 would be reacted is deposited by sputtering. Thereafter, RTA is carried out under the conditions of 400° C. to 500° C. and approximately 60 seconds so as to completely silicidize the polycrystalline silicon layers. Thus, the effects obtained by the semiconductor device according to the first embodiment can be similarly obtained by the semiconductor device according to the second modified example.

### Second Embodiment

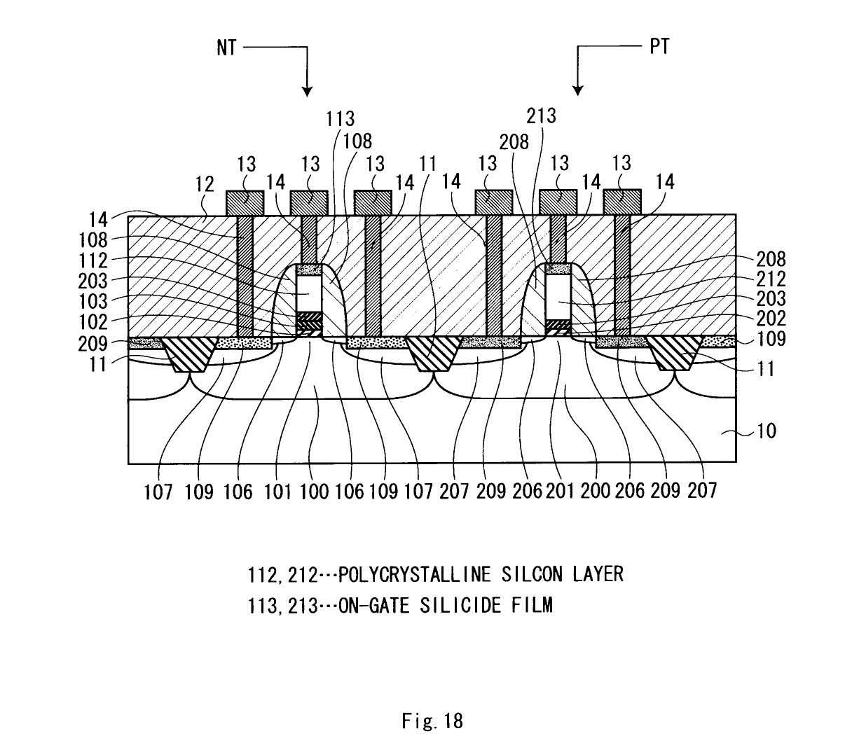

FIG. 18 is a cross-sectional view of a semiconductor device according to a second embodiment of the present invention.

The present embodiment is different from the first embodiment in that a polycrystalline silicon layer is set to be a p+ doping layer and an on-gate silicide film on the polycrystalline silicon layer is formed of a material which exhibits a low Schottky barrier to a p-type region. Same reference numerals will be given to denote components substantially same as those of the first embodiment, and description thereof will not be repeated.

An n-type MIS transistor NT has a stacked gate structure including a gate insulating film 102, an nMIS metal gate electrode 103, a pMIS metal gate electrode 203 (and unillustrated barrier film), a polycrystalline silicon layer 112, and an on-gate silicide film 113. A p-type MIS transistor PT has a stacked gate structure including a gate insulating film 202, the pMIS metal gate electrode 203 (and unillustrated barrier film), a polycrystalline silicon layer 212, and an on-gate silicide film 213.

The polycrystalline silicon layers 112 and 212 are p+ doping layers having the same concentration. The on-gate silicide layers 113 and 213 are formed of the same material, and are formed of a material which exhibits a low Schottky barrier to the p-type region depending on dopant in the polycrystalline silicon layers 112 and 212. The on-gate silicide films 113 and 213 can be formed of, for example, PtSi, Pd₂Si, NiSi, or the like.

For the sake of simplicity of processes and the like, it is desirable that the on-gate silicide films 113 and 213 be formed of the same material as that of the pMIS silicide film 109 formed in the source/drain regions of the p-type MIS transistor PT.

In the semiconductor device having the above-described structure, the source/drain regions have the dual silicide structure, and work functions of the gate electrodes are respectively determined by the metal gate electrodes included in the n-type MIS transistor and p-type MIS transistor. Further, the polycrystalline silicon layers on the metal gate electrodes are both p+ doping layers. In addition, the on-gate silicide films are each formed of a material which exhibits a low Schottky barrier to the p-type region.

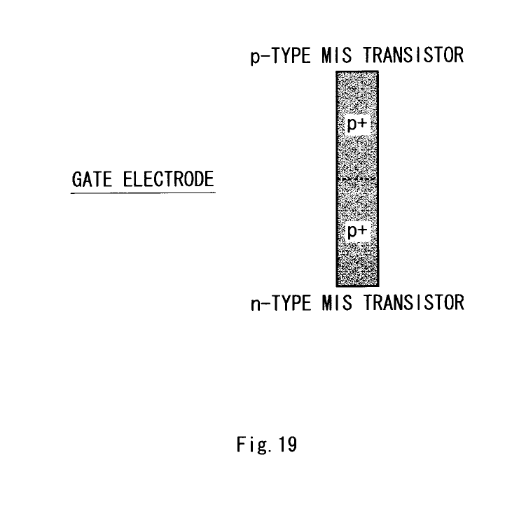

FIG. 19 is a top view schematically showing the gate electrodes of the semiconductor device according to the present embodiment. As shown in FIG. 19, an interface between the n-type region and the p-type region is not formed in forming the gate electrodes of the semiconductor device having the dual silicide structure. In other words, there is no interface between the polycrystalline silicon layers having different conductivity types, so that deterioration of an interface resistance due to dopant compensation can be prevented. In addition, there is no interface between the on-gate silicide films formed of different materials, so that a defect in forming a silicide film can be prevented and disconnection of the gate electrode can be prevented. Moreover, a combination of materials of the on-gate silicide film and dopant of the polycrystalline silicon layer can be selected so that the Schottky barrier would be lowered in the p-type region. Accordingly, the deterioration of resistance in the interface between silicide and silicon formed on each gate electrode can be prevented.

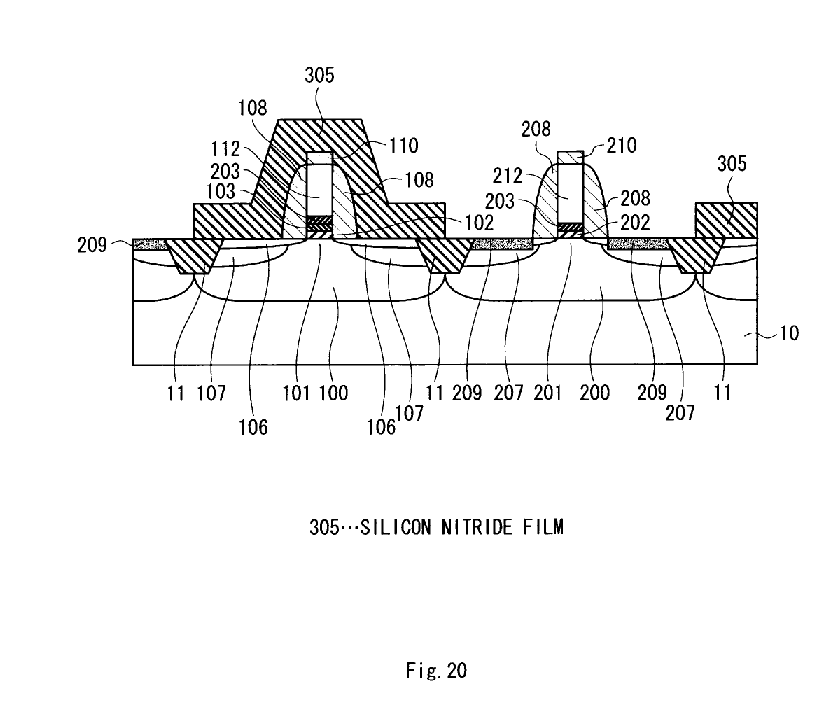

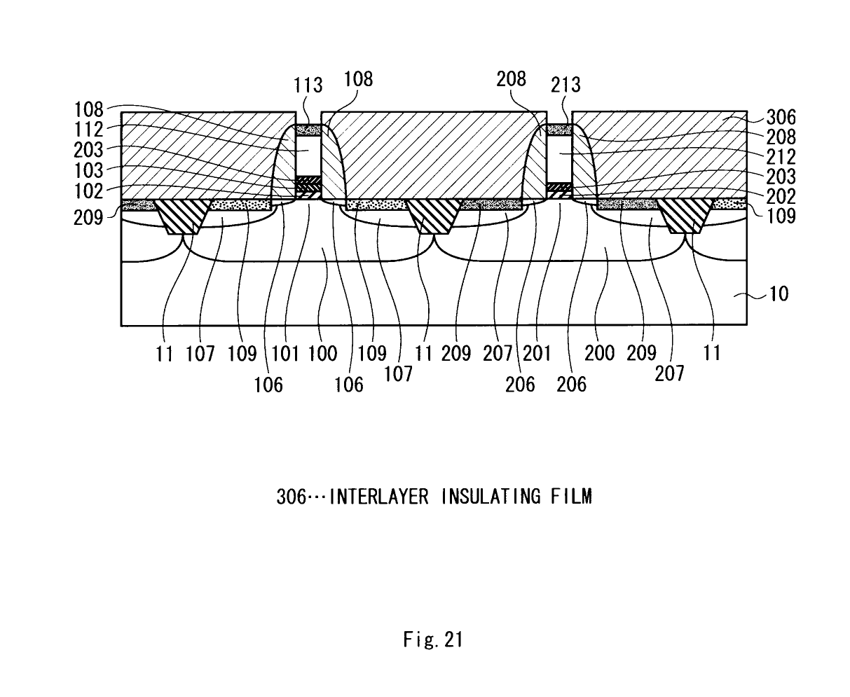

The structure of the semiconductor device according to the present embodiment will be described by referring to the manufacturing processes shown in FIGS. 20 and 21. However, the description will be given only of portions whose processes are different from those of FIGS. 4 to 15. The processes before FIG. 20 are similar to those shown in FIGS. 4 to 10 in the first embodiment. However, p+ doping layers are formed on the entire surface of the polycrystalline silicon layers 112 and 212. Note that B ion implantation is performed into the polycrystalline silicon layers 112 and 212 under the conditions of, for example, 2 keV and 5.0×10¹⁵ cm⁻².

Next, only the n-type MIS transistor region is coated with a silicon oxide film (or silicon nitride film) 305 for forming the source/drain regions by the dual silicide process. Then, hydrofluoric acid treatment is carried out to remove a natural oxide film, so that the pMIS silicide film 209 is formed in the source/drain regions of the p-type MIS transistor PT (FIG. 20). The subsequent processes are similar to those of the first embodiment shown in FIGS. 11 to 14.

Subsequently, the on-gate silicide films 113 and 213 are formed by using a silicide material corresponding to the dopant in the polycrystalline silicon layers 112 and 212 (in the present embodiment, a p+ doping layer is employed, and thus the dopant is B, or the like). Here, the p+ doping layer is formed in the polycrystalline silicon layers 112 and 212. Accordingly, a material which exhibits a low Schottky barrier to the p-type region, such as PtSi, Pd₂Si, or NiSi, can be used (FIG. 21). In the following, the semiconductor device shown in FIG. 18 is obtained by similar processes to those of the first embodiment.

In the above-described first embodiment, the polycrystalline silicon layer is formed of the n+ doping layer and the on-gate silicide film is formed of the nMIS silicide film which exhibits a low Schottky barrier to the n-type region. In terms of the interface resistance, the combination of the polycrystalline silicon (n+ doping layer)/nMIS silicide film has a physically lower interface resistance (tunneling probability of electrons is lower) than the combination of the polycrystalline silicon (p+ doping layer)/pMIS silicide film. Accordingly, the former combination has a larger advantage for the demand to lower the resistance in the interface between silicon and silicide on a gate electrode.

In contrast, in the above-described second embodiment, the polycrystalline silicon layer is formed of the p+ doping layer and the on-gate silicide film is formed of the pMIS silicide film which exhibits a low Schottky barrier to the p-type region. A satisfactory silicide film can be formed more easily on the polycrystalline silicon layer into which B ion implantation is performed, than on the polycrystalline silicon layer into which P or As ion implantation is performed. Accordingly, the former has a larger advantage for the demand to increase manufacturing yields.

In essence, the combination of silicon and silicide in the gate electrode can be appropriately selected depending on the consistency with the current processes, and an interface resistance to be achieved, and the like.

As described above, the present invention has been described by using the first and second embodiments. However, the present invention is not limited to the above-described embodiments. For example, the present invention can be combined with various modifications, or can be variously changed without departing from the scope thereof in its practical phase. In addition, each of the aforementioned embodiments includes various inventions of various steps and stages, and it is possible to extract inventions of various steps and stages by properly combining the multiple constituent features disclosed in the embodiments. For example, even if a several constituent features are deleted from the entire constituent features shown in the present embodiments, in the case where at least one of the problems described in the background of the invention that is intended to describe the problems to be solved by the present invention can be solved, and where at least one of the effects described in the summary of the invention that is intended to describe the effects of the present invention is achieved, the configuration in which the constituent features are deleted can be extracted as an invention.

What is claimed is:

1. A semiconductor device comprising:
a semiconductor substrate;
an n-type MIS transistor which is formed on the semiconductor substrate and has a first metal gate electrode and a first polycrystalline silicon layer formed on the first metal gate electrode;
a p-type MIS transistor which is formed on the semiconductor substrate and has a second metal gate electrode and a second polycrystalline silicon layer, the second metal gate electrode containing at least one metallic element different from that of the first metal gate electrode, and the second polycrystalline silicon layer being formed on the second metal gate electrode and having the same conductivity type as that of the first polycrystalline silicon layer;
a first silicide film formed in source and drain regions of the n-type MIS transistor;
a second silicide film which is formed in source and drain regions of the p-type MIS transistor and contains at least one metallic element different from that of the first silicide film;
a first on-gate silicide film formed on the first polycrystalline silicon layer; and
a second on-gate silicide film which is formed on the second polycrystalline silicon layer and is formed of the same material as that of the first on-gate silicide film.

2. The semiconductor device according to claim 1, wherein
the first and second polycrystalline silicon layers are an n-type, and
the first and second on-gate silicide films have the same composition as that of the first silicide film.

3. The semiconductor device according to claim 2, wherein
threshold voltages of the n-type MIS transistor and the p-type MIS transistor are determined not by the conductivity type of the first and second polycrystalline silicon layers but by the first and second metal gate electrodes, respectively.

4. The semiconductor device according to claim 2, wherein
the first silicide film contains at least one metal selected from the group consisting of Y, Yb, and Er, and
the second silicide film contains at least one metal selected from the group consisting of Pt, Pd, and Ni.

5. The semiconductor device according to claim 4, wherein
the first metal gate electrode is formed of TaC.

6. The semiconductor device according to claim 5, wherein
the second metal gate electrode is formed of WN.

7. The semiconductor device according to claim 6, wherein
gate insulating films of the n-type MIS transistor and the p-type MIS transistor are formed of HfSiON.

8. The semiconductor device according to claim 1, wherein
the first and second polycrystalline silicon layers are a p-type, and
the first and second on-gate silicide films have the same composition as that of the second silicide film.

9. The semiconductor device according to claim 8, wherein
threshold voltages of the n-type MIS transistor and the p-type MIS transistor are determined not by the conductivity type of the first and second polycrystalline silicon layers but by the first and second metal gate electrodes, respectively.

10. The semiconductor device according to claim 8, wherein
the first silicide film contains at least one metal selected from the group consisting of Y, Yb, and Er, and
the second silicide film contains at least one metal selected from the group consisting of Pt, Pd, and Ni.

11. The semiconductor device according to claim 10, wherein
the first metal gate electrode is formed of TaC.

12. The semiconductor device according to claim 11, wherein
the second metal gate electrode is formed of WN.

13. The semiconductor device according to claim 12, wherein
gate insulating films of the n-type MIS transistor and the p-type MIS transistor are formed of HfSiON.

14. A semiconductor device comprising:
a semiconductor substrate;
an n-type MIS transistor which is formed on the semiconductor substrate and has a first metal gate electrode;
a p-type MIS transistor which is formed on the semiconductor substrate and has a second metal gate electrode containing at least one metallic element different from that of the first metal gate electrode;
a first silicide film formed in source and drain regions of the n-type MIS transistor;
a second silicide film which is formed in source and drain regions of the p-type MIS transistor and contains at least one metallic element different from that of the first silicide film;
a first on-gate silicide film formed on the first metal gate electrode; and
a second on-gate silicide film which is formed on the second metal gate electrode and is formed of the same material as that of the first on-gate silicide film.

15. A method for manufacturing a semiconductor device comprising:
forming an n-type well region and a p-type well region in a surface of a semiconductor substrate, the n-type well region and the p-type well region being isolated from each other by an element isolation insulating film;
forming a gate insulating film on the semiconductor substrate;
forming a first metal film on the n-type well region;
forming a second metal film on the p-type well region, the second metal film containing at least one metallic element different from that of the first metal film;
forming a polycrystalline silicon film on the first and second metal films;
etching the gate insulating film, the first metal film, the second metal film, and the polycrystalline silicon film in order to form a gate electrode on each of the n-type well region and the p-type well region;
forming a first silicide film in source and drain regions corresponding to the gate electrode on the n-type well region;
forming a second silicide film in source and drain regions corresponding to the gate electrode on the p-type well region, the second silicide film containing at least one metallic element different from that of the first silicide film; and
forming a same silicide film on the polycrystalline silicon film forming the gate electrode on each of the n-type well region and the p-type well region.

16. The method for manufacturing a semiconductor device according to claim 15, further comprising:
depositing an interlayer insulating film on the entire surface of the semiconductor substrate;
planarizing the interlayer insulating film; and
exposing the polycrystalline silicon film from the surface of the interlayer insulating film.

17. The method for manufacturing a semiconductor device according to claim 15, further comprising:
adding an n-type impurity into the polycrystalline silicon film, wherein
in forming the silicide film on the polycrystalline silicon film, a material having a low Schottky barrier to an n-type region is used.

18. The method for manufacturing a semiconductor device according to claim 17, further comprising:
removing the second metal film formed on the first metal film.

19. The method for manufacturing a semiconductor device according to claim 15, further comprising:
adding a p-type impurity into the polycrystalline silicon film, wherein
in forming the silicide film on the polycrystalline silicon film, a material having a low Schottky barrier to a p-type region is used.

20. The method for manufacturing a semiconductor device according to claim 19, further comprising:
removing the second metal film formed on the first metal film.
